(19) United States
(12) Patent Application Publication
(10) Pub. No.: US 2007/0007553 A1
(43) Pub. Date: Jan. 11, 2007

(54) Memory device

(75) Inventors: Yasuo Murakuki, Kyoto (JP); Takashi Miki, Hyogo (JP)

Correspondence Address: STEPTOE & JOHNSON LLP, 1330 CONNECTICUT AVE., NW, WASHINGTON, DC, 20036, US

(73) Assignee: Matsushita Electric Industrial Co., Ltd., Kadoma-shi (JP)

(21) Appl. No.: 11/477,788

(22) Filed: Jun. 30, 2006

(30) Foreign Application Priority Data
Jul. 1, 2005 (JP) 2005-193230

(51) Int. Cl. H01L 27/10

(52) U.S. Cl. 257/206

(57) ABSTRACT

An object of the present invention is to provide, in an FeRAM memory device fixed to a cell plate, a memory device in which RES_N (source line) of a reset transistor for resetting a storage node has a low resistance. A memory cell (101) includes a ferroelectric capacitance, a first MOS transistor for selecting the memory cell, and a second MOS transistor which is a reset transistor for resetting the storage node. Potential is supplied to RES_N (source line) (impurity activation region) of the second MOS transistor through the following two conductive layers: an impurity activation region which is a conductive layer below an upper electrode of the ferroelectric capacitance, and a bit-line formation wiring layer making up a bit line BL. This configuration makes it possible to supply potential to RES_N (source line) with a low resistance and perform a stable operation.

### FIELD OF THE INVENTION

The present invention relates to a semiconductor storage device (memory device) and particularly relates to a semiconductor storage device including a ferroelectric.

### BACKGROUND OF THE INVENTION

In recent years, semiconductor storage devices are known in which data is stored in a nonvolatile manner by using ferroelectric films as the insulating films of capacitors. In such a semiconductor storage device, a transition of the polarization of a ferroelectric exhibits a hysteresis characteristic. Even when voltage applied to the ferroelectric becomes zero, residual polarization is present in the ferroelectric and nonvolatile data is stored using the residual polarization.

The configuration of a memory cell of conventional Fe (ferroelectric) RAM including such a ferroelectric and a reading/writing method thereof are disclosed in, for example, JP2723386B.

Regarding the conventional semiconductor storage device, however, the layout of a memory array is not discussed. When a memory array is laid out, the following problems arise:

FIG. 28 shows the conventional configuration. Reference numeral 2801 denotes a memory cell. FIG. 29 shows a sectional view taken along A2801-A2801′ of FIG. 28. FIG. 30 shows a circuit diagram of the memory cell 2801.

The memory cell 2801 is an ordinary memory cell. As shown in FIG. 30, the memory cell 2801 comprises a ferroelectric capacitance 601 (an example of a first information storage element) formed on a silicon substrate, a first MOS transistor 602 (an example of a first connector) for selecting the memory cell, and a second MOS transistor 603 (an example of a second connector) which is a reset transistor for controlling a storage node such that the storage node is connected to RES_N (source line). The memory cell 2801 is connected via an impurity activation region OD. The memory cells 2801 are arranged in a matrix, so that a memory array (memory cell array) is formed.

The ferroelectric capacitance 601 comprises a ferroelectric capacitance upper electrode FQ (a second electrode of the first information storage element), a ferroelectric FE, and a ferroelectric capacitance lower electrode SS (a first electrode of the first information storage element). The ferroelectric capacitance upper electrode FQ is connected to CP (cell plate line).

Further, a gate electrode PS of the first MOS transistor 602 is connected to WL (word line) and one of the impurity activation regions OD (a second electrode of the first connector) is connected to a bit-line formation wiring layer MO, that is, BL (bit line) via bit line contact CB.

Moreover, a gate electrode PS of the second MOS transistor 603 is connected to RES (storage node reset signal line) and one of the impurity activation regions OD (the second electrode of the first connector) is connected to RES_N (source line). RES_N (source line) is formed of the impurity activation regions OD.

The impurity activation region OD under ferroelectric capacitance contact CS connected to the ferroelectric capacitance lower electrode SS forms the other impurity activation region (a first electrode of the first connector) of the first MOS transistor 602 and the other impurity activation region OD (a first electrode of the second connector) of the second MOS transistor 603 (the first electrode of the first information storage element, the first electrode of the first connector, and the first electrode of the second connector are connected to one another), so that the storage node is formed.

In the FeRAM memory cell, during standby, CP (cell plate line) is fixed at the potential of VCP {=VCC (power supply potential)/2}, RES_N (source line) is fixed at the potential of VCP, BL (bit line) is fixed at the potential of VCP, the potential of WL (word line) is fixed at the level of VSS (ground potential), and the potential of RES (storage node reset signal line) is fixed at the level of VPP (potential higher than VCC). Thus a potential difference between the upper electrode FQ and the lower electrode SS of the ferroelectric capacitance 601 is eliminated, so that data is stored. However, RES_N (source line) is laid out in the impurity activation region OD, and thus RES_N (source line) in the memory array has a high resistance (point A in FIG. 28). For this reason, when VCP fluctuates in potential, a potential difference occurs between the upper electrode FQ and the lower electrode SS of the ferroelectric capacitance 601 and data corruption may occur (Problem 1).

In another method, RES_N (source line) is backed by metal wiring so as to have a resistance equal to or lower than a desired resistance. The configuration of the method is shown in FIG. 31. Reference numeral 3001 denotes a memory cell. FIG. 32 shows a sectional view taken along A3001-A3001′ of FIG. 31. FIG. 33 shows a sectional view taken along B3001-B3001′ of FIG. 31.

As shown in FIG. 33, a first metal wire layer M1 is connected via contact CW to an impurity activation region OD which forms RES_N (source line).

In this configuration, the first metal wire layer M1 is disposed between memory cell group 1 and memory cell group 2, so that the periodicity of the layout of the memory cells is lost between the memory cell group 1 and the memory cell group 2.

Therefore, at least the characteristics of the memory cell group 1 and the memory cell group 2 are adversely affected (Problem 2).

FIG. 34 shows a memory device in which barrier films including memory arrays are disposed. Reference numeral 3301 denotes a memory cell. FIG. 35 shows a sectional view taken along A3301-A3301′ of FIG. 34. FIG. 36 shows a sectional view taken along B3301-B3301′ of FIG. 34.

Barrier films HB are disposed above the memory cells with a first metal wire layer M1 being interposed between the barrier films HB.

This configuration requires separation (L4 in FIG. 34) between the barrier films HB and an overlap (L3 in FIG. 34) from the end of the barrier film HB to the memory cells, inevitably increasing a layout area (Problem 3). Further, an impurity activation region OD making up RES_N (source line) increases in peripheral length and area, and thus a junction leakage may increase or the characteristics of a transistor including the impurity activation region OD may be deteriorated (Problem 4).

It is an object of the present invention to provide a semiconductor storage device which can solve Problems 1 to 4.

### DISCLOSURE OF THE INVENTION

In order to solve the problems, a memory device of the present invention comprises a memory array in which memory cells are arranged in a matrix, the memory cell being formed on a silicon substrate and including a first information storage element having at least first and second electrodes, a first connector having at least first and second electrodes, and a second connector having at least first and second electrodes, wherein the first electrode of the first information storage element, the first electrode of the first connector, and the first electrode of the second connector are connected to one another via an impurity activation region, and the second electrode of the first connector is selectively connected to a bit line via a word line, wherein potential is supplied to the second electrode of the second connector through a plurality of conductive layers disposed below the first electrode and the second electrode of the first information storage element.

The memory device of the present invention comprises a barrier film including the memory array, and potential is supplied to the second electrode of the second connector through a plurality of conductive layers disposed below the barrier film.

According to the memory device of the present invention, the memory array includes a second information storage element not used for storing information.

According to the memory device of the present invention, one of the plurality of conductive layers is identical to a conductive layer making up the bit line.

According to the memory device of the present invention, one of the plurality of conductive layers is identical to a conductive layer making up the bit line, has a substantially identical shape to the bit line, and is formed at substantially regular intervals.

According to the memory device of the present invention, one of the plurality of conductive layers is identical to a conductive layer making up the second electrode of the first information storage element.

According to the memory device of the present invention, one of the plurality of conductive layers is identical to a conductive layer making up the second electrode of the first information storage element, has a substantially identical shape to the second electrode of the information storage element, and is formed at substantially regular intervals.

The memory device of the present invention comprises a plurality of memory cell groups in which the second electrodes of the second connectors of the plurality of memory cells connected to the same word line are connected via a first conductive layer having a continuous shape.

According to the memory device of the present invention, potential is supplied to the first conductive layer through a plurality of conductive layers disposed below the first electrode or the second electrode of the first information storage element.

The memory device of the present invention comprises a barrier film so shaped as to include the memory array, the first conductive layer having a potential fixed by one or more conductive layers disposed below the barrier film.

The memory device of the present invention comprises a dummy memory cell including a second information storage element not used for storing information, the continuous shape being divided in the dummy memory cell.

According to the memory device of the present invention, the first information storage element is a ferroelectric capacitance.

According to the memory device of the present invention, the barrier film is a barrier film for preventing characteristics deterioration of the first information storage element in the diffusion process of a metal wiring layer.

According to the memory device of the present invention, the first connector is an MOS transistor.

According to the memory device of the present invention, the second connector is an MOS transistor.

According to the memory device of the present invention, the second connector is a resistance element.

The present invention can provide a memory device which can supply potential to a second electrode of a second connector with a low resistance and a small area, keep the periodicity of the shape of a memory array to the greatest extent possible, achieve high packaging density and yields, and enable a stable operation.

### BRIEF DESCRIPTION OF THE DRAWINGS

FIG. 1 is a plan view showing a memory device according to Embodiment 1 of the present invention;

FIG. 2 is a sectional view taken along A101-A101′ of FIG. 1;

FIG. 3 is a sectional view taken along A102-A102′ of FIG. 1;

FIG. 4 is a sectional view taken along line B101-B101′ of FIG. 1;

FIG. 5 is a sectional view taken along B102-B102′ of FIG. 1;

FIG. 6 is a circuit diagram showing a dummy memory cell according to Embodiment 1 of the present invention;

FIG. 7 is a plan view showing a memory device according to Embodiment 2 of the present invention;

FIG. 8 is a sectional view taken along A801-A801′ of FIG. 7;

FIG. 9 is a sectional view taken along A802-A802′ of FIG. 7;

FIG. 10 is a sectional view taken along B801-B801′ of FIG. 7;

FIG. 11 is a sectional view taken along B802-B802′ of FIG. 7;

FIG. 12 is a circuit diagram showing a dummy memory cell according to Embodiment 2 of the present invention;

FIG. 13 is a plan view showing a memory device according to Embodiment 3 of the present invention;

FIG. 14 is a sectional view taken along line A1301-A1301′ of FIG. 13;

FIG. 15 is a sectional view taken along A1302-A1302′ of FIG. 13;

FIG. 16 is a sectional view taken along B1301-B1301′ of FIG. 13;

FIG. 17 is a sectional view taken along B1302-B1302′ of FIG. 13;

FIG. 18 is a plan view showing a memory device according to Embodiment 4 of the present invention;

FIG. 19 is a sectional view taken along A1801-A1801′ of FIG. 18;

FIG. 20 is a sectional view taken along A1802-A1802′ of FIG. 18;

FIG. 21 is a sectional view taken along B1801-B1801′ of FIG. 18;

FIG. 22 is a sectional view taken along B1802-B1802′ of FIG. 18;

FIG. 23 is a plan view showing a memory device according to Embodiment 5 of the present invention;

FIG. 24 is a sectional view taken along A2301-A2301′ of FIG. 23;

FIG. 25 is a sectional view taken along A2302-A2302′ of FIG. 23;

FIG. 26 is a sectional view taken along B2301-B2301′ of FIG. 23;

FIG. 27 is a sectional view taken along B2302-B2302′ of FIG. 23;

FIG. 28 is a plan view showing a conventional memory device;

FIG. 29 is a sectional view taken along A2801-A2801′ of FIG. 28;

FIG. 30 is a circuit diagram showing an ordinary memory cell;

FIG. 31 is a plan view showing a conventional memory device;

FIG. 32 is a sectional view taken along A3001-A3001′ of FIG. 31;

FIG. 33 is a sectional view taken along B3001-B3001′ of FIG. 31;

FIG. 34 is a plan view showing a conventional memory device;

FIG. 35 is a sectional view taken along A3301-A3301′ of FIG. 34; and

FIG. 36 is a sectional view taken along B3301-B3301′ of FIG. 34.

### DESCRIPTION OF THE EMBODIMENTS

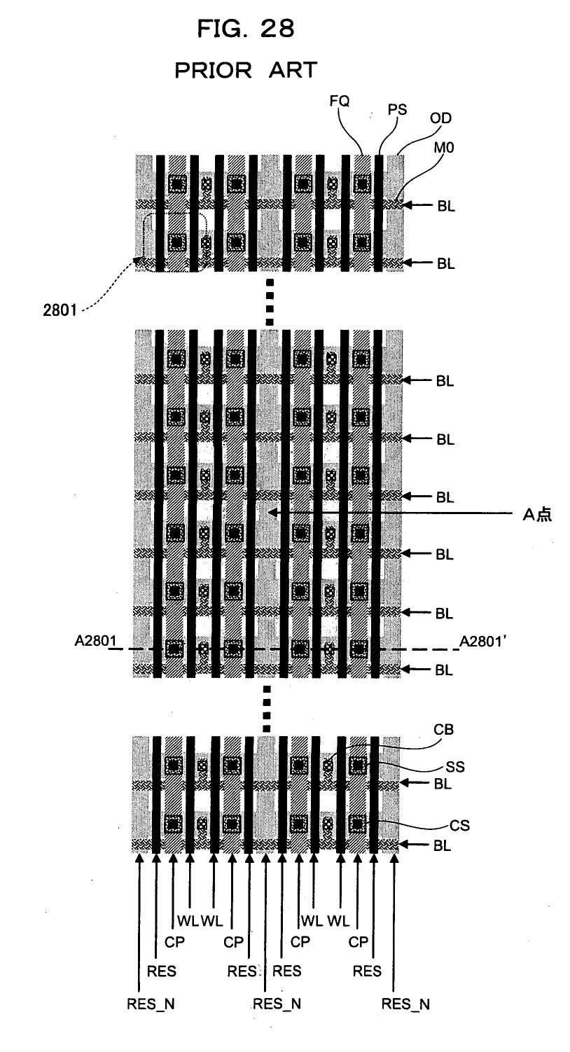

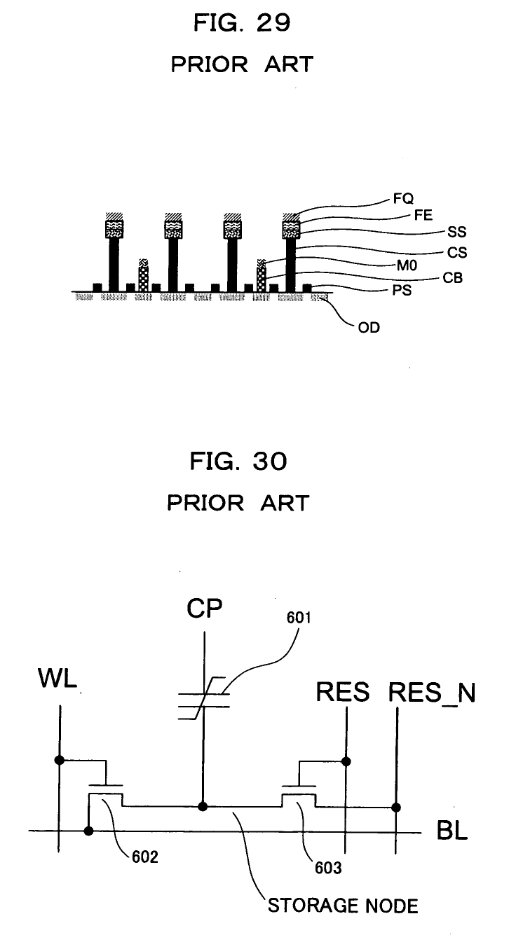

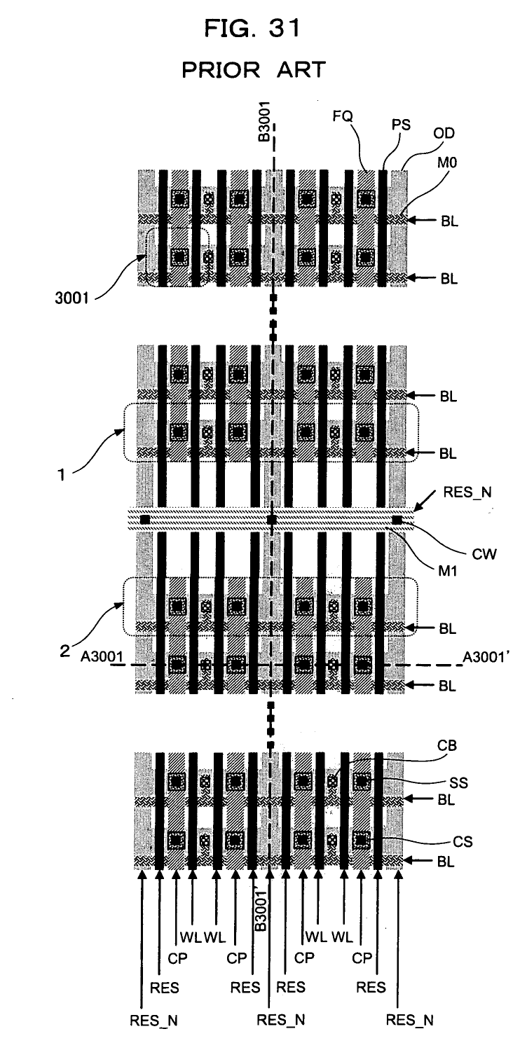

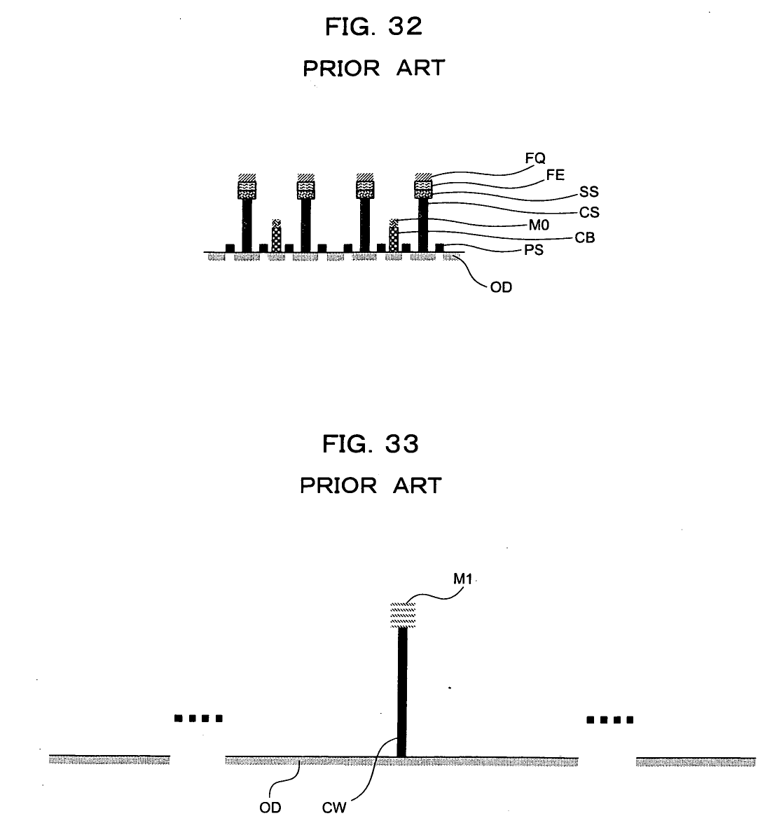

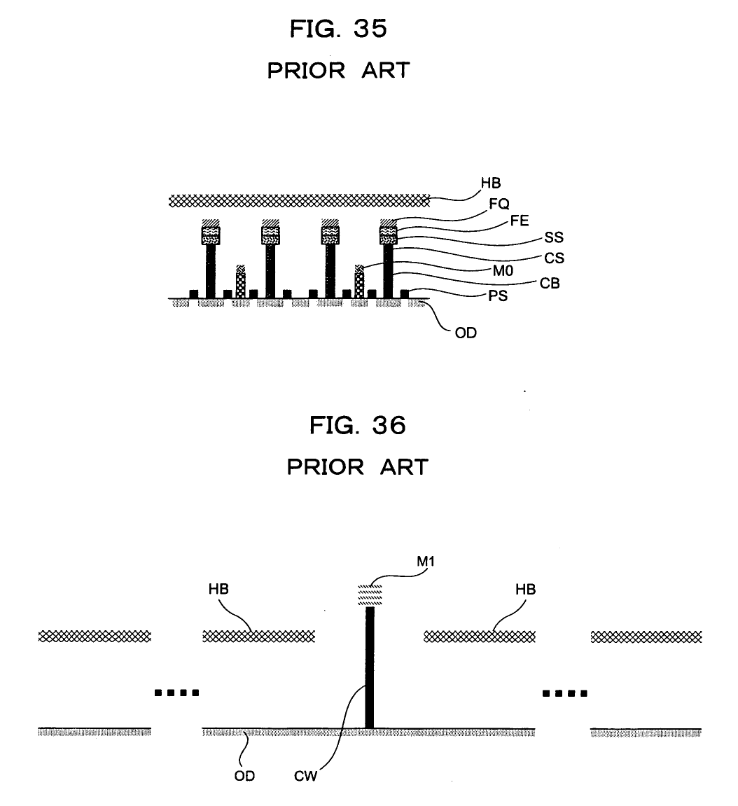

The following will describe embodiments of the present invention in accordance with the accompanying drawings. The same configurations as FIGS. 28 to 36 are indicated by the same reference numerals and the explanation thereof is omitted.

### Embodiment 1

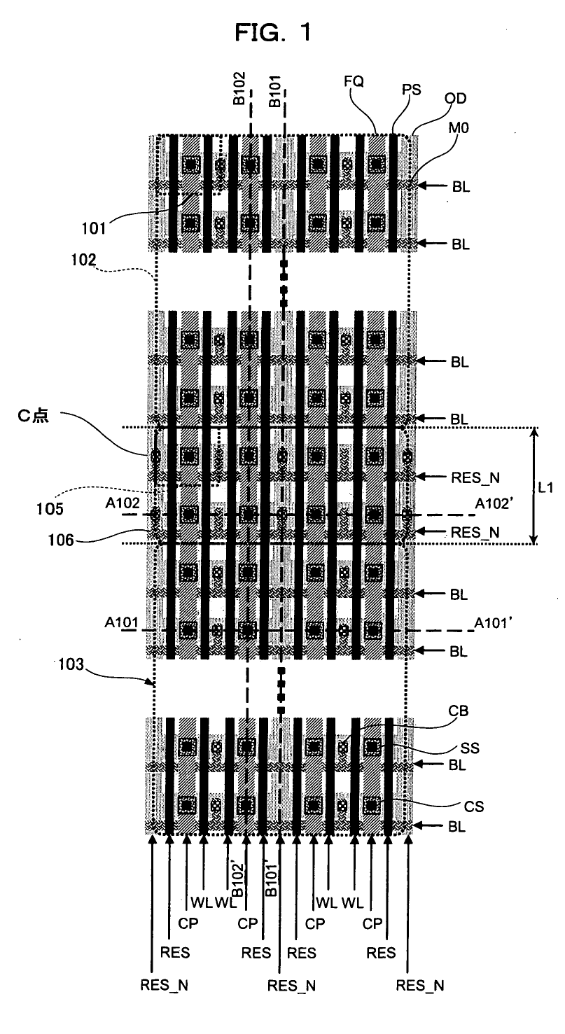

Referring to FIGS. 1 to 6, the following will describe Embodiment 1 of the present invention. Embodiment 1 accomplishes memory devices described in claims 1, 3, 4, 5, 12, 14 and 15.

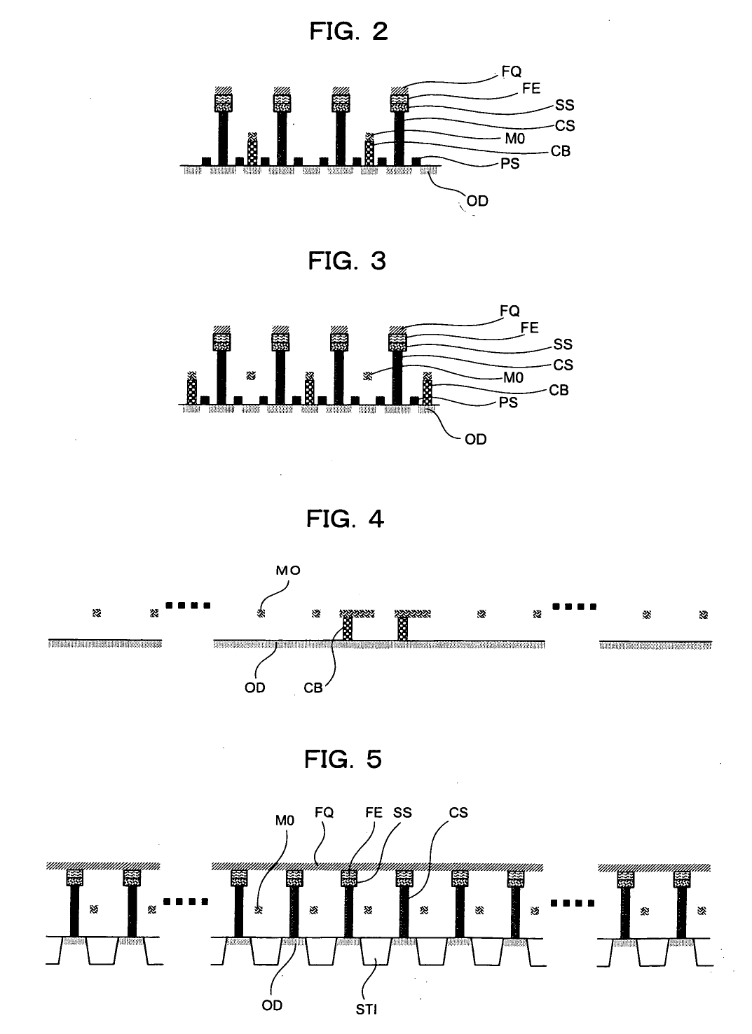

FIG. 1 is a plan view showing the memory device according to Embodiment 1 of the present invention. FIGS. 2, 3, 4, and 5 are sectional views taken along A101-A101′, A102-A102′, B101-B101′, and B102-B102′ of FIG. 1, respectively.

Reference numeral 101 of FIG. 1 denotes an ordinary memory cell which is identical in configuration to the memory cell 2801 shown in FIGS. 28 and 30 and comprises a single ferroelectric capacitance 601 and two MOS transistors 602 and 603. Reference numerals 102 and 103 of FIG. 1 denote memory arrays in which the memory cells 101 are arranged.

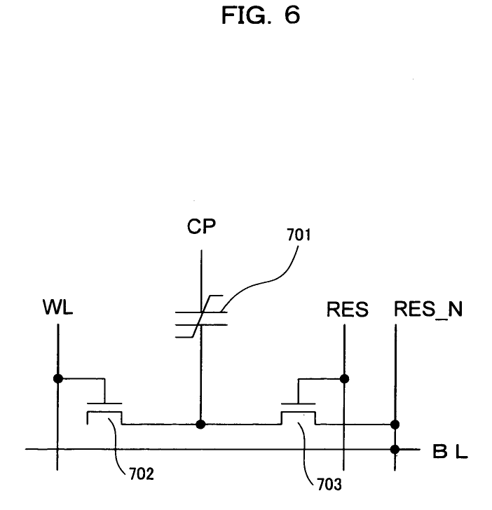

Reference numeral 105 of FIG. 1 denotes a dummy memory cell which does not store information. The dummy memory cell 105 comprises a single ferroelectric capacitance and two MOS transistors. FIG. 6 is a circuit diagram of the dummy memory cell 105. In FIG. 6, reference numeral 701 denotes a ferroelectric dummy capacitance and reference numerals 702 and 703 denote MOS transistors.

The dummy memory cell 105 is identical in configuration to the ordinary memory cell 101. However, as shown in FIG. 3, one of impurity activation regions OD (a second electrode of a first connector) of the first MOS transistor 702 is not connected to a bit-line formation wiring layer MO, that is, BL (bit line), and the ferroelectric dummy capacitance 701 not storing information is provided.

In FIG. 5, reference numeral ST1 denotes a device isolation region for isolation between the memory cell 101 and the dummy memory cell 105.

The bit-line formation wiring layer MO disposed in the dummy memory cell 105 is connected to the potential of RES_N (source line) outside the memory array and connected, via bit line contact CB, to the impurity activation region OD with the potential of RES_N (source line) in the dummy memory cell 105 (FIGS. 1, 3, 4 and 6) In other words, the potential of RES_N (source line) in the dummy memory cell 105 is set at the potential of BL (bit line), and the potential (the potential of the impurity activation region OD) of RES_N (source line) in the array is more strongly fixed.

As described above, potential is supplied to the second MOS transistor 703 of the dummy memory cell 105 through the following two conductive layers: the impurity activation region OD which is a conductive layer below an upper electrode FQ of the ferroelectric capacitance 701, and the bit-line formation wiring layer MO making up the bit line BL, so that potential can be supplied to RES_N (source line) with a low resistance and a stable operation can be performed.

Further, as shown in FIG. 3, the bit-line formation wiring layer MO used for supplying potential to RES_N (source line) in the dummy memory cell 105 is substantially identical in shape to the bit-line formation wiring layer MO (bit line BL) of another memory cell 101 and is formed at substantially regular intervals, so that the periodicity of the shape of the bit-line formation wiring layer MO (bit line BL) can be kept, an abnormal shape or the like caused by lost periodicity can be prevented, and a break or short circuit on the bit line BL can be prevented, improving yields.

As shown in FIGS. 1 and 3, the dummy memory cell 105 comprises the ferroelectric dummy capacitance 701 made up of a ferroelectric FE, the upper electrode FQ, a lower electrode SS, and ferroelectric capacitance contact CS which are identical in shape to those of the ordinary memory cell 101. It is thus possible to keep the periodicity of the shapes of the ferroelectric capacitances 601 and 701 and prevent the characteristics deterioration and an abnormal shape of the ferroelectric capacitance 601 due to lost periodicity, thereby preventing an adverse effect on the characteristics of the memory cell 101.

### Embodiment 2

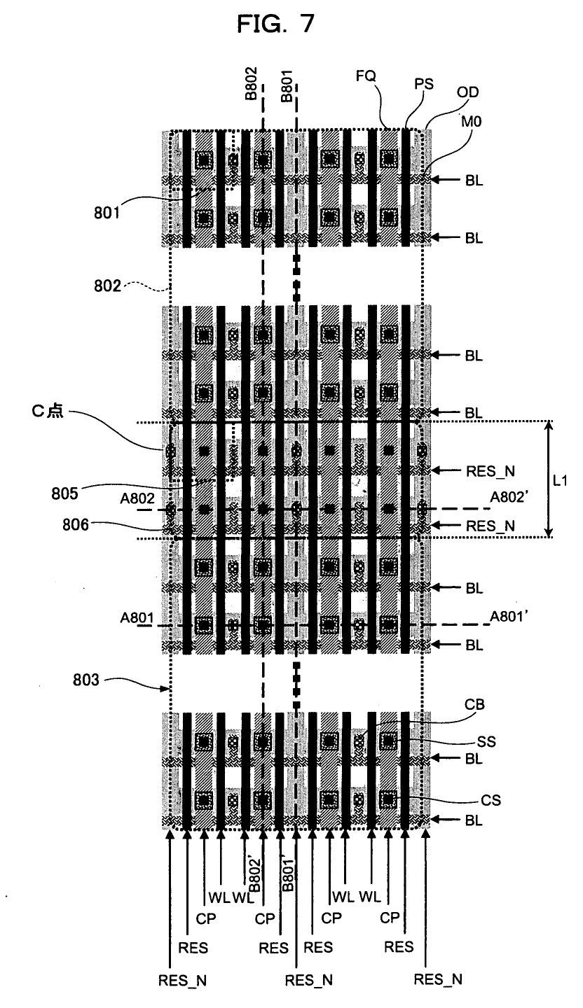

Referring to FIGS. 7 to 11, the following will describe Embodiment 2 of the present invention. Embodiment 2 accomplishes a memory device described in claims 1, 6, and 7.

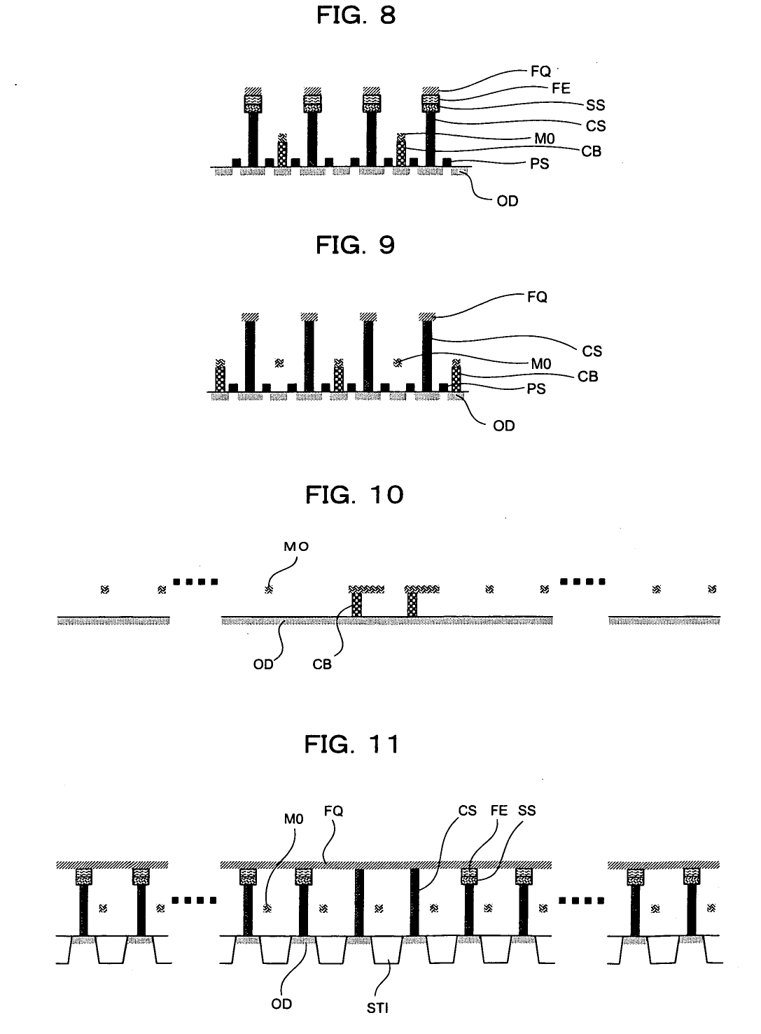

FIG. 7 is a plan view showing the memory device according to Embodiment 2 of the present invention. FIGS. 8, 9, 10, and 11 are sectional views taken along A801-A801′, A802-A802′, B801-B801′, and B802-B802′ of FIG. 7, respectively.

Reference numeral 801 of FIG. 7 denotes the same ordinary memory cell as the memory cell 101. Reference numerals 802 and 803 of FIG. 7 denote memory arrays in which the memory cells 801 are arranged.

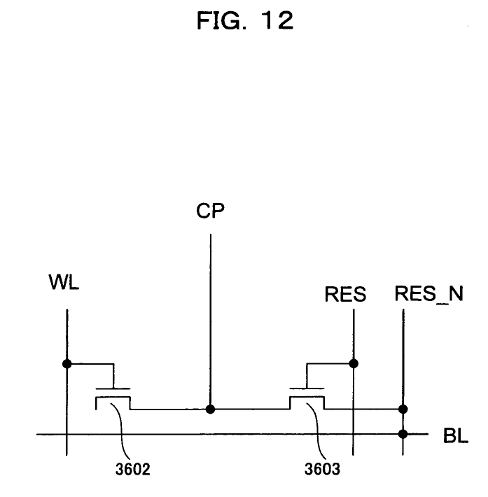

Reference numeral 805 of FIG. 7 denotes a dummy memory cell which does not store information. As shown in FIG. 12, the dummy memory cell 805 comprises two MOS transistors 3602 and 3603. The dummy memory cell 805 comprises no ferroelectric dummy capacitance.

A bit-line formation wiring layer MO disposed in the dummy memory cell 805 of FIG. 7 is connected to RES_N (source line) outside the memory array and connected, via bit line contact CB, to an impurity activation region OD with the potential of RES_N (source line) in the dummy memory cell 805 (FIGS. 7, 9, and 10). The conductive layer of a ferroelectric capacitance upper electrode FQ disposed in the dummy memory cell 805 of FIG. 7 is connected to the potential of RES_N (source line) outside the memory array and connected, via ferroelectric capacitance contact CS, to the impurity activation region OD with the potential of RES_N (source line) in the dummy memory cell 805 (FIGS. 7, 9, and 11).

As described above, potential is supplied to the second MOS transistor 3603 of the dummy memory cell 805 through the following three conductive layers: the impurity activation region OD which is a conductive layer below the upper electrode FQ of the ferroelectric capacitance, the bit-line formation wiring layer MO making up BL (bit line), and the conductive layer of the upper electrode (a second electrode of a first information storage element) FQ of the ferroelectric capacitance making up CP (cell plate line), so that the potential of RES_N (source line) in the array (impurity activation region OD) is more strongly fixed.

With this configuration, by using the upper electrode FQ making up CP (cell plate line), potential can be supplied with a low resistance to the second MOS transistor 3603 to which RES_N (source line) is connected, so that a stable operation can be performed.

Further, as shown in FIG. 7, the conductive layer making up the upper electrode FQ of the ferroelectric capacitance in the dummy memory cell 805 is substantially identical in shape to that of the ordinary memory cell 801 and is formed at substantially regular intervals, so that the periodicity of the shape of the upper electrode FQ of the ferroelectric capacitance can be kept, an abnormal shape or the like caused by lost periodicity can be prevented, and a break or short circuit on the upper electrode FQ can be prevented, improving yields.

### Embodiment 3

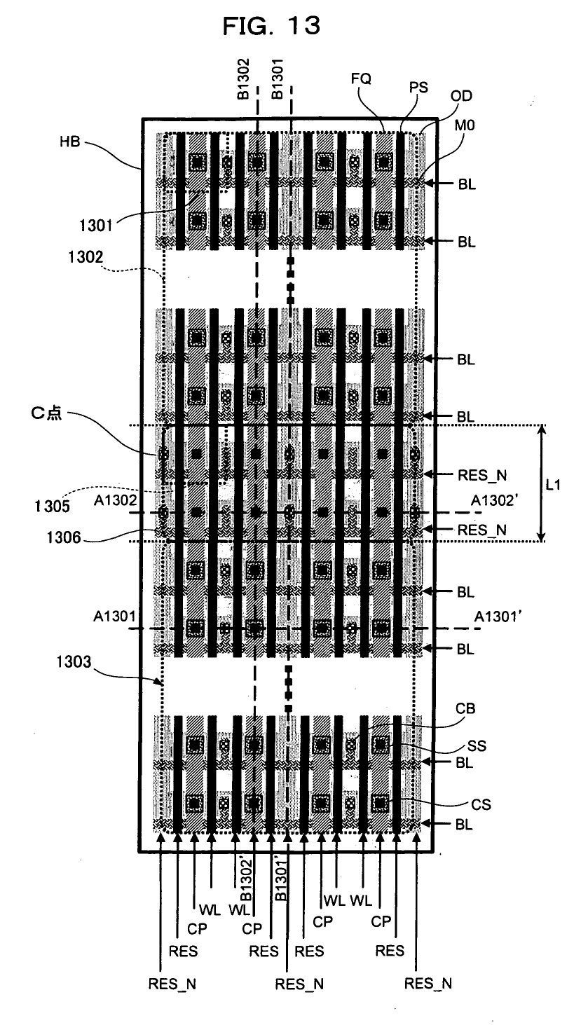

Referring to FIGS. 13 to 17, the following will describe Embodiment 3 of the present invention. Embodiment 3 accomplishes memory devices described in claims 2, 3, 4, 5, 6, 7, and 13.

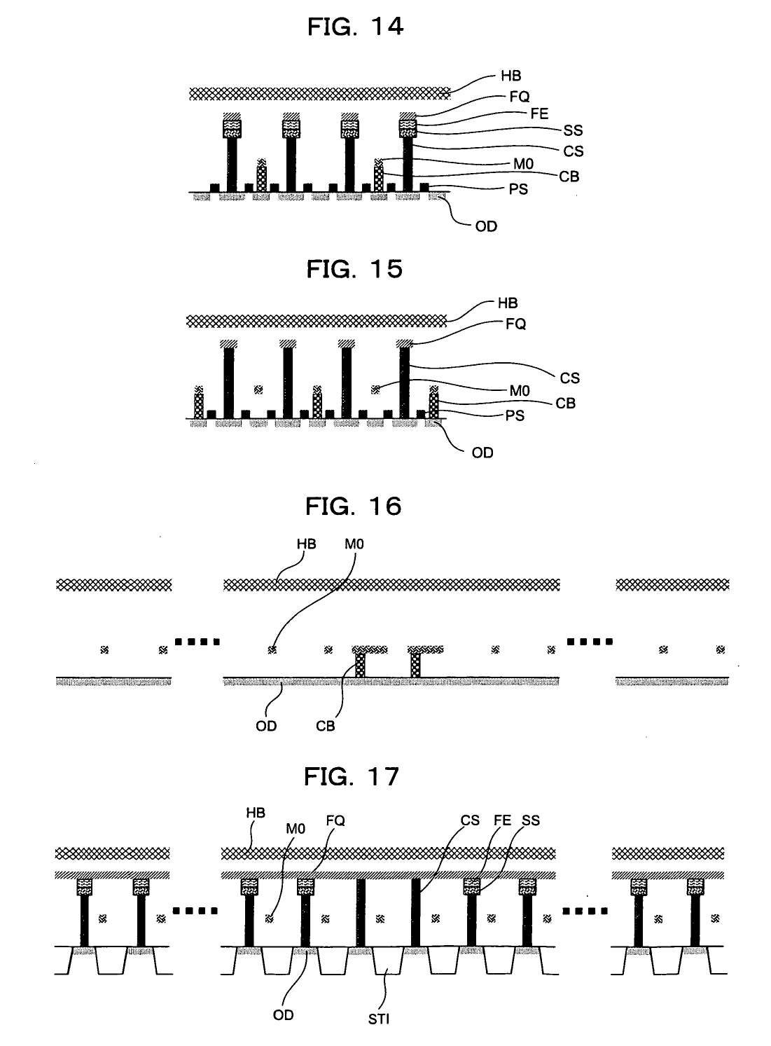

FIG. 13 is a plan view showing the memory device according to Embodiment 3 of the present invention. FIGS. 14, 15, 16, and 17 are sectional views taken along A1301-A1301′, A1302-A1302′, B1301-B1301′, and B1302-B1302′ of FIG. 13, respectively.

Reference numeral 1301 of FIG. 13 denotes the same memory cell as the ordinary memory cell 101. Reference numerals 1302 and 1303 denote memory arrays in which the memory cells 1301 are arranged.

Reference numeral 1305 of FIG. 13 denotes a dummy memory cell which is identical to the dummy memory cell 805 of Embodiment 2 and does not store information. The dummy memory cell 1305 is made up of two MOS transistors and a bit-line formation wiring layer MO disposed in the dummy memory cell 1305 is connected to the potential of RES_N (source line) outside the memory array and connected, via bit line contact CB, to an impurity activation region OD with the potential of RES_N (source line) in the dummy memory cell 1305 (FIGS. 13, 15, and 16).

The conductive layer of an upper electrode FQ disposed in the dummy memory cell 1305 is connected to the potential of RES_N (source line) outside the memory array and connected, via ferroelectric capacitance contact CS, to the impurity activation region OD with the potential of RES_N (source line) in the dummy memory cell 1305 (FIGS. 13, 15, and 17).

Further, the memory arrays are included in a barrier film HB. The barrier film HB prevents the characteristics of a ferroelectric capacitance from deteriorating in the diffusion process of a metal wiring layer.

As described above, potential is supplied to RES_N (source line) through the following two conductive layers: the impurity activation region OD which is a conductive layer below the barrier film HB including the memory arrays, and the bit-line formation wiring layer MO making up BL (bit line), so that the potential of RES_N (source line) (impurity activation region OD) in the array is more strongly fixed.

The upper electrode FQ making up CP (cell plate line) and the bit-line formation wiring layer MO making up BL (bit line) are connected via ferroelectric capacitance contact CS, so that potential can be supplied to RES_N (source line) with a low resistance, the potential of RES_N (source line) (impurity activation region OD) in the array can be more strongly fixed, and a stable operation can be performed.

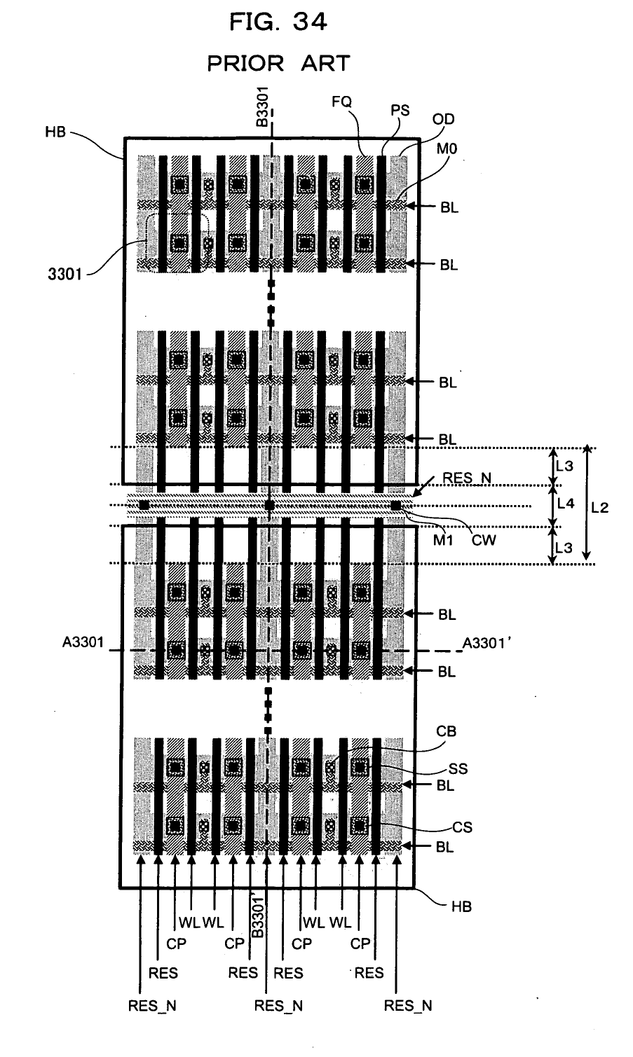

Further, potential is supplied only through the conductive layer below the barrier film HB to a second MOS transistor 3603 to which RES_N (source line) is connected, so that L1 of FIG. 13 can be much smaller than L2 of FIG. 34 illustrated in Background of the Invention.

Moreover, as shown in FIG. 13, the conductive layer of the upper electrode FQ in the dummy memory cell 1305 is substantially identical in shape to that of the ordinary memory cell 1301 and is formed at substantially regular intervals, so that the periodicity of the shape of the upper electrode FQ can be kept, an abnormal shape or the like caused by lost periodicity can be prevented, and a break or short circuit on the upper electrode FQ can be prevented, improving yields.

Further, the bit-line formation wiring layer MO used for supplying potential to RES_N (source line) in the dummy memory cell 1305 is substantially identical in shape to the bit-line formation wiring layer MO (bit line BL) of another memory cell 1301 and is formed at substantially regular intervals, so that the periodicity of the shape of the bit-line formation wiring layer MO (bit line BL) can be kept, an abnormal shape or the like caused by lost periodicity can be prevented, and a break or short circuit on the bit line BL can be prevented, improving yields.

### Embodiment 4

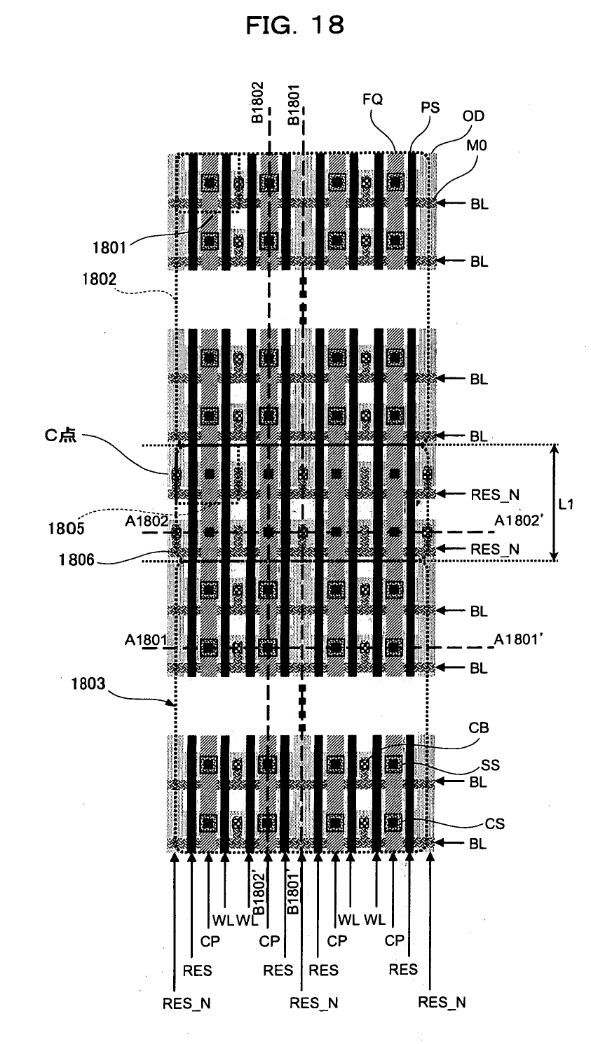

Referring to FIGS. 18 to 22, the following will describe Embodiment 4 of the present invention. Embodiment 4 accomplishes memory devices described in claims 8, 9, and 11.

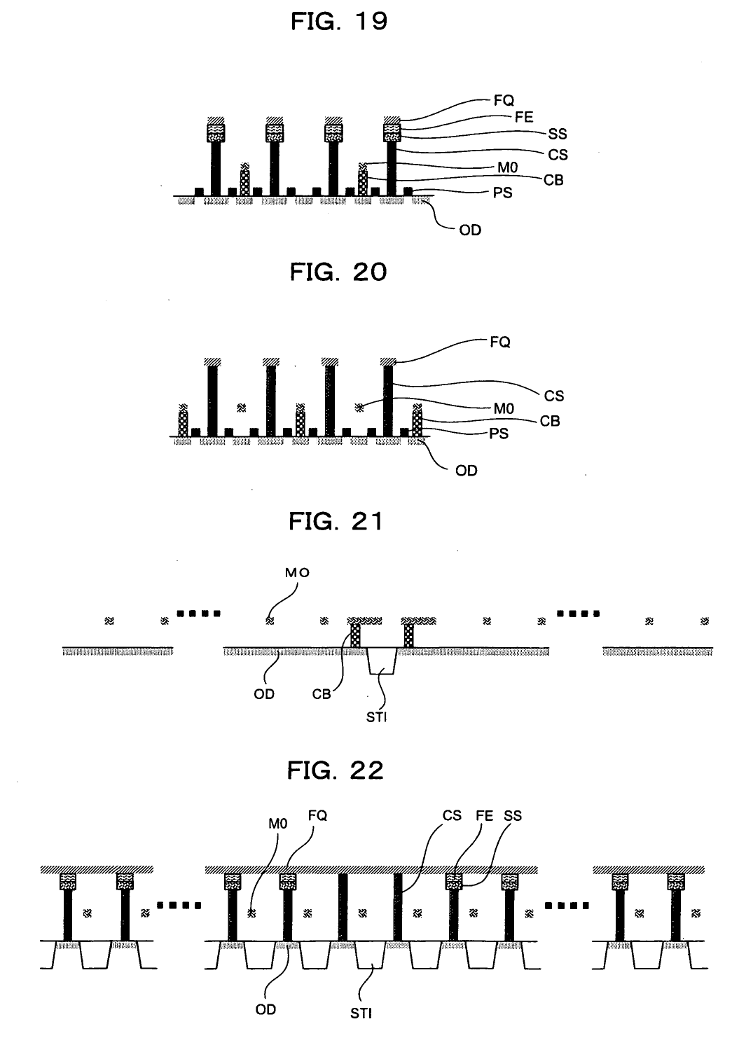

FIG. 18 is a plan view showing the memory device according to Embodiment 4 of the present invention. FIGS. 19, 20, 21, and 22 are sectional views taken along A1801-A1801′, A1802-A1802′, B1801-B1801′, and B1802-B1802′ of FIG. 18, respectively.

Reference numeral 1801 of FIG. 18 denotes the same memory cell as the ordinary memory cell 101. Reference numerals 1802 and 1803 denote memory arrays in which the memory cells 1801 are arranged.

Reference numeral 1805 of FIG. 18 denotes a dummy memory cell which is identical to the dummy memory cell 805 of Embodiment 2 and does not store information. The dummy memory cell 1805 is made up of two MOS transistors, and a bit-line formation wiring layer MO disposed in the dummy memory cell 1805 is connected to the potential of RES_N (source line) outside the memory array and connected, via bit line contact CB, to an impurity activation region OD with the potential of RES_N (source line) in the dummy memory cell 1805 (FIGS. 18, 20, and 21). Reference numeral 1806 denotes a dummy memory array in which the dummy memory cells 1805 are arranged.

The conductive layer of an upper electrode FQ disposed in the dummy memory cell 1805 is connected to the potential of RES_N (source line) outside the memory array and connected, via ferroelectric capacitance contact CS, to the impurity activation region OD with the potential of RES_N (source line) in the dummy memory cell 1805 (FIGS. 18, 20, and 22).

As shown in FIGS. 18 and 21, RES_N (source line), which is connected via the impurity activation region OD in the direction of WL (word line), is divided by a device isolation region ST1 in the direction of WL (word line), so that RES_N (source line) of the memory array 1802 and the memory array 1803 is divided. Thus the memory device comprises the memory array 1802 and the memory array 1803 in which the impurity activation regions OD of second MOS transistors of the two or more memory cells 1801 connected to the same WL (word line) are connected via RES_N (source line) (a first conductive layer with a continuous shape). In other words, the memory device comprises sets of memory cells. In the dummy memory array 1806, the device isolation region ST1 divides the impurity activation region OD with the potential of RES_N (source line). Thus a limit on the shape of the impurity activation region OD (for example, a limit on the maximum peripheral length and the maximum area) can be eliminated, so that the impurity activation region OD can have a desired shape (below the limit on the maximum peripheral length and the maximum area), potential can be supplied to RES_N (source line) with a low resistance, and a stable operation can be performed.

Potential is supplied to RES_N (source line) through the following three conductive layers: the impurity activation region OD which is a conductive layer below the upper electrode FQ of the ferroelectric capacitance, the bit-line formation wiring layer MO making up BL (bit line), and the conductive layer of the upper electrode FQ making up CP (cell plate line), so that the potential of RES_N (source line) (impurity activation region OD) in the memory array is more strongly fixed.

Further, as shown in FIG. 18, the conductive layer of the upper electrode FQ in the dummy memory cell 1805 is substantially identical in shape to that of the ordinary memory cell 1801 and is formed at substantially regular intervals, so that the periodicity of the shape of the upper electrode FQ can be kept, and an abnormal shape or the like caused by lost periodicity can be prevented, improving yields.

### Embodiment 5

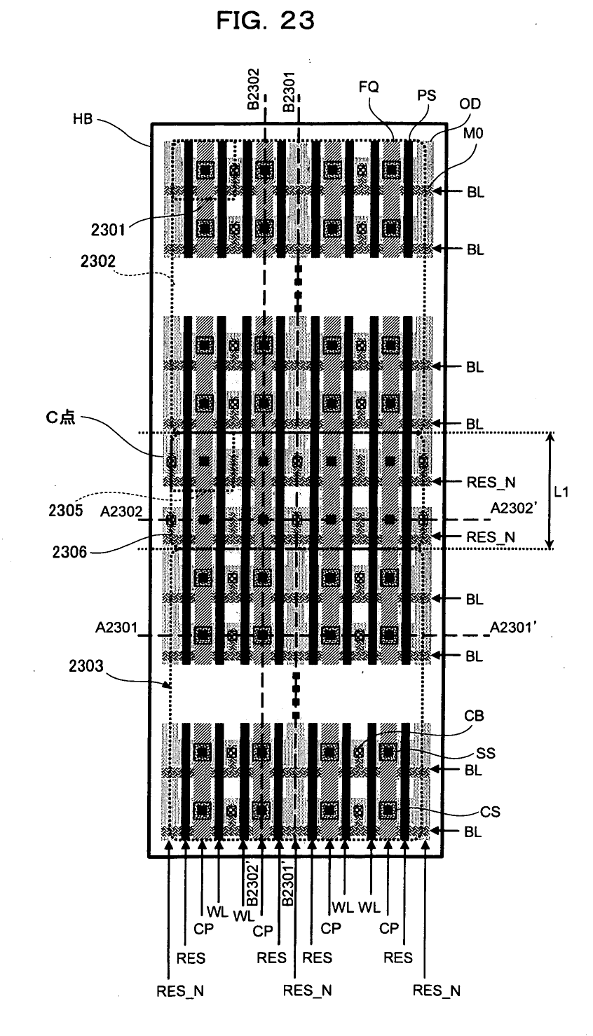

Referring to FIGS. 23 to 27, the following will describe Embodiment 5 of the present invention. Embodiment 5 accomplishes memory devices described in claims 8, 10, 11, and 13.

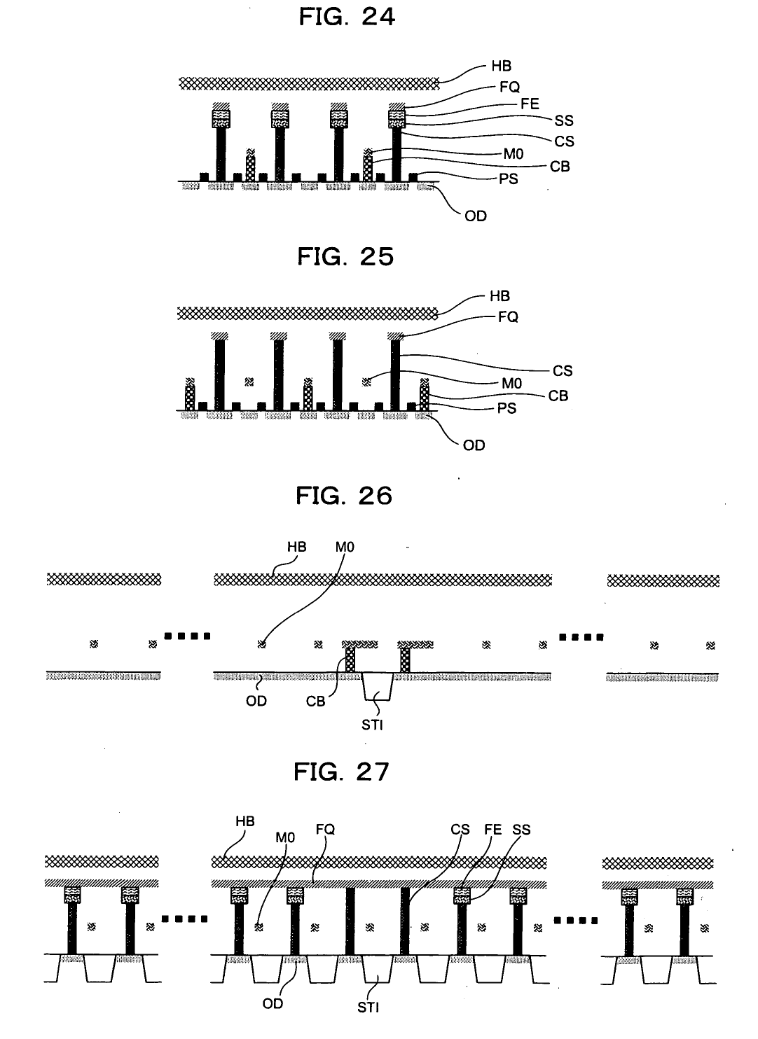

FIG. 23 is a plan view showing the memory device according to Embodiment 5 of the present invention. FIGS. 24, 25, 26, and 27 are sectional views taken along A2301-A2301′, A2302-A2302′, B2301-B2301′, and B2302-B2302′ of FIG. 23, respectively.

Reference numeral 2301 of FIG. 23 denotes an ordinary memory cell which is the same as the ordinary memory cell 101. Reference numerals 2302 and 2303 denote memory arrays in which the memory cells 2301 are arranged.

Reference numeral 2305 of FIG. 23 denotes a dummy memory cell which is identical to the dummy memory cell 805 of Embodiment 2 and does not store information. The dummy memory cell 2305 is made up of two MOS transistors and a bit-line formation wiring layer MO disposed in the dummy memory cell 2305 is connected to the potential of RES_N (source line) outside the memory array and connected, via bit line contact CB, to an impurity activation region OD with the potential of RES_N (source line) in the dummy memory cell 2305 (FIGS. 23, 25, and 26). Reference numeral 2306 denotes a dummy memory array in which the dummy memory cells 2305 are arranged.

The conductive layer of an upper electrode FQ disposed in the dummy memory cell 2305 is connected to the potential of RES_N (source line) outside the memory array and connected, via ferroelectric capacitance contact CS, to the impurity activation region OD with the potential of RES_N (source line) in the dummy memory cell 2305 (FIGS. 23, 25, and 27).

The memory arrays are included in a barrier film HB. The barrier film HB prevents the characteristics of a ferroelectric capacitance from deteriorating in the diffusion process of a metal wiring layer.

As shown in FIGS. 23 and 26, RES_N (source line), which is connected via the impurity activation region OD in the direction of WL (word line), is divided by a device isolation region ST1 in the direction of WL (word line), so that RES_N (source line) of the memory array 2802 and the memory array 2803 is divided. Thus, the memory device comprises the memory array 2302 and the memory array 2303 in which the impurity activation regions OD of the second MOS transistors of the two or more memory cells 2301 connected to the same WL (word line) are connected via RES_N (source line) (a first conductive layer with a continuous shape). In other words, the memory device comprises sets of memory cells. In the dummy memory array 2306, the device isolation region ST1 divides the impurity activation region OD with the potential of RES_N (source line). Thus a limit on the shape of the impurity activation region OD (for example, a limit on the maximum peripheral length and the maximum area) can be eliminated, so that the impurity activation region OD can have a desired shape (below the limit on the maximum peripheral length and the maximum area), potential can be supplied to RES_N (source line) with a low resistance, and a stable operation can be performed.

Potential is supplied to RES_N (source line) through the following three conductive layers: the impurity activation region OD which is a conductive layer below the barrier film HB including the memory arrays, the bit-line formation wiring layer MO making up BL (bit line), and the conductive layer of the upper electrode FQ making up CP (cell plate line), so that the potential of RES_N (source line) (impurity activation region OD) in the array is more strongly fixed. As described above, the memory device comprises the barrier film HB which is so shaped as to include the memory arrays, and the potential of RES_N (source line) (first conductive layer) is fixed through one or more conductive layers disposed below the barrier film HB.

Further, potential is supplied only through the conductive layer below the barrier film HB to a second MOS transistor to which RES_N (source line) is connected, so that L1 of FIG. 23 can be much smaller than L2 of FIG. 34 illustrated in Background of the Invention.

Further, as shown in FIG. 23, the conductive layer of the upper electrode FQ in the dummy memory cell 2305 is substantially identical in shape to that of the ordinary memory cell 2301 and is formed at substantially regular intervals, so that the periodicity of the shape of the upper electrode FQ can be kept, and an abnormal shape or the like caused by lost periodicity can be prevented, improving yields.

The present embodiment described a 2T (two MOS transistors)/1C (ferroelectric capacitance) memory cell. A 1T (a single MOS transistor for selecting a memory sell)/1C (ferroelectric capacitance) memory cell may be used. In this case, a second MOS transistor (second connector) is formed of a resistance element.

### INDUSTRIAL APPLICABILITY

The present invention provides a semiconductor storage device which can achieve high yields and a stable operation with a small area. The present invention is particularly effective for a semiconductor storage device including a ferroelectric.

What is claimed is:

1. A memory device comprising a memory array in which memory cells are arranged in a matrix, each memory cell being formed on a silicon substrate and including a first information storage element having at least first and second electrodes, a first connector having at least first and second electrodes, and a second connector having at least first and second electrodes, wherein the first electrode of the first information storage element, the first electrode of the first connector, and the first electrode of the second connector are connected to one another via an impurity activation region, and the second electrode of the first connector is selectively connected to a bit line via a word line, wherein
potential is supplied to the second electrode of the second connector through a plurality of conductive layers disposed below one of the first electrode and the second electrode of the first information storage element.

2. The memory device according to claim 1, wherein the memory array includes a second information storage element not used for storing information.

3. The memory device according to claim 1, wherein one of the plurality of conductive layers is identical to a conductive layer making up the bit line.

4. The memory device according to claim 1, wherein one of the plurality of conductive layers is identical to a conductive layer making up the bit line, has a substantially identical shape to the bit line, and is formed at substantially regular intervals.

5. The memory device according to claim 1, wherein one of the plurality of conductive layers is identical to a conductive layer making up the second electrode of the first information storage element.

6. The memory device according to claim 1, wherein one of the plurality of conductive layers is identical to a conductive layer making up the second electrode of the first information storage element, has a substantially identical shape to the second electrode of the information storage element, and is formed at substantially regular intervals.

7. The memory device according to claim 1, wherein the first information storage element is a ferroelectric capacitance.

8. The memory device according to claim 1, wherein the first connector is an MOS transistor.

9. The memory device according to claim 1, wherein the second connector is an MOS transistor.

10. The memory device according to claim 1, wherein the second connector is a resistance element.

11. A memory device comprising a memory array in which memory cells are arranged in a matrix, each memory cell being formed on a silicon substrate and including a first information storage element having at least first and second electrodes, a first connector having at least first and second electrodes, and a second connector having at least first and second electrodes, wherein the first electrode of the first information storage element, the first electrode of the first connector, and the first electrode of the second connector are connected to one another via an impurity activation region, and the second electrode of the first connector is selectively connected to a bit line via a word line, wherein
the memory device further comprises a barrier film including the memory array, and
potential is supplied to the second electrode of the second connector through a plurality of conductive layers disposed below the barrier film.

12. The memory device according to claim 11, wherein the memory array includes a second information storage element not used for storing information.

13. The memory device according to claim 11, wherein one of the plurality of conductive layers is identical to a conductive layer making up the bit line.

14. The memory device according to claim 11, wherein one of the plurality of conductive layers is identical to a conductive layer making up the bit line, has a substantially identical shape to the bit line, and is formed at substantially regular intervals.

15. The memory device according to claim 11, wherein one of the plurality of conductive layers is identical to a conductive layer making up the second electrode of the first information storage element.

16. The memory device according to claim 11, wherein one of the plurality of conductive layers is identical to a conductive layer making up the second electrode of the first information storage element, has a substantially identical shape to the second electrode of the information storage element, and is formed at substantially regular intervals.

17. The memory device according to claim 11, wherein the first information storage element is a ferroelectric capacitance.

18. The memory device according to claim 11, wherein the barrier film is a barrier film for preventing characteristics deterioration of the first information storage element in a diffusion process of a metal wiring layer.

19. The memory device according to claim 11, wherein the first connector is an MOS transistor.

20. The memory device according to claim 11, wherein the second connector is an MOS transistor.

21. The memory device according to claim 11, wherein the second connector is a resistance element.

22. A memory device comprising a memory array in which memory cells are arranged in a matrix, each memory cell being formed on a silicon substrate and including a first information storage element having at least first and second electrodes, a first connector having at least first and second electrodes, and a second connector having at least first and second electrodes, wherein the first electrode of the first information storage element, the first electrode of the first connector, and the first electrode of the second connector are connected to one another via an impurity activation region, and the second electrode of the first connector is selectively connected to a bit line via a word line, wherein
the memory device further comprising a plurality of memory cell groups in which the second electrodes of the second connectors of a plurality of memory cells connected to the same word line are connected via a first conductive layer having a continuous shape.

23. The memory device according to claim 22, wherein potential is supplied to the first conductive layer through at least one conductive layer disposed below one of the first electrode and the second electrode of the first information storage element.

24. The memory device according to claim 22, further comprising a barrier film shaped to include the memory cell array, wherein the first conductive layer has a potential fixed by at least one conductive layer disposed below the barrier film.

25. The memory device according to claim 22, further comprising a dummy memory cell including a second information storage element not used for storing information, wherein the continuous shape is divided in the dummy memory cell.

26. The memory device according to claim 22, wherein the first information storage element is a ferroelectric capacitance.

27. The memory device according to claim 22, wherein the barrier film is a barrier film for preventing characteristics deterioration of the first information storage element in a diffusion process of a metal wiring layer.

28. The memory device according to claim 22, wherein the first connector is an MOS transistor.

29. The memory device according to claim 22, wherein the second connector is an MOS transistor.

30. The memory device according to claim 22, wherein the second connector is a resistance element.
